(19) United States
(12) Patent Application Publication
(10) Pub. No.: US 2026/0351534 A1
(43) Pub. Date: Nov. 5, 2026

(54) SEMICONDUCTOR DEVICE MANUFACTURING SYSTEM, MANUFACTURING METHOD, AND SERVER

(71) Applicant: HITACHI HIGH-TECH CORPORATION, Minato-ku, Tokyo (JP)

(72) Inventors: Tooru ARAMAKI, Tokyo (JP); Go SAITO, Tokyo (JP); Makoto SATAKE, Tokyo (JP); Takefumi KAKINUMA, Tokyo (JP)

(21) Appl. No.: 19/099,883

(22) PCT Filed: Oct. 5, 2023
(86) PCT No.: PCT/JP2023/036318

§ 371 Date: Jan. 30, 2025

(51) Int. Cl. H01J 37/32; H10P 50/24; H10P 72/00; H10P 74/20

(52) U.S. Cl. CPC H01J 37/3299; H01J 37/32935; H10P 50/24; H10P 72/0421; H10P 72/0604; H10P 74/203; H01J 2237/334

(57) ABSTRACT

An object of the invention to provide a system that detects a shape defect that cannot be obtained only by top-view geometric dimension data and derives an optimal processing condition in a depth direction of an etching shape. Therefore, in the semiconductor device manufacturing system according to the invention, optimization of an etching parameter is executed in at least one of etching steps based on correlation data between the etching parameter and a change amount of a feature and based on a change amount of an acquired feature, the feature is a value obtained from secondary electron data or interference light data from a surface of a sample, the change amount of the feature is a difference between the feature and a target value of the feature, the change amount of the acquired feature is a change amount of the feature acquired for each depth of an etching shape formed by the semiconductor manufacturing apparatus, and each of the etching step isa step of processing conditions of the semiconductor manufacturing apparatus corresponding to each depth of the etching shape formed by the semiconductor manufacturing apparatus.

### TECHNICAL FIELD

The present invention relates to a semiconductor device manufacturing system, a manufacturing method, and a server.

### BACKGROUND ART

A plasma etching system is currently a part of semiconductor manufacturing tool for manufacturing a semiconductor device approaching miniaturization of an atomic level. One requirement of a device manufacturing apparatus is improvement in uniformity. In manufacturing a semiconductor device approaching an atomic level, it has been found that it is insufficient to simply measure a dimension in a lateral direction of a semiconductor device by observing the semiconductor device from an upper surface of a wafer and then perform uniformization based on measured data. For example, a measurement device includes a CD-SEM, but only a dimension of a surface of a pattern can be obtained based on top-view geometric plane dimension data obtained by the CD-SEM, and thus a bowing shape or a notch shape of a portion slightly deeper from the surface of the pattern cannot be measured. Accordingly, even with the same critical dimension (CD) value, it is not possible to detect a three-dimensional geometric defect of a pattern. If a defect cannot be detected in this manner, it is apparent that a defect will occur in an ion implantation process or a CVD process after etching. Since defective shapes relate not only to a temperature of a sample during etching but also to plasma characteristics, complicated etching parameter control is required.

In the related art, as disclosed in PTL 1, based on a CD value that is top-view geometric dimension data, a temperature value of an electrostatic chuck is fed back based on a variation in the CD value in a wafer surface to achieve a uniform CD value in the wafer surface and improve a yield in the wafer surface.

### CITATION LIST

### Patent Literature

PTL 1: JP5925943

### SUMMARY OF INVENTION

### Technical Problem

However, since the technique according to the related art is a technique for making the CD value uniform, it is not possible to cope with a situation where a defect such as a bowing shape or a notch shape occurs in a depth direction even though the CD value is the same. Since the technique is a technique of feeding back a temperature of an electrostatic chuck, it is not possible to cope with a defect of a pattern shape caused by a plasma characteristic.

Further, since the bowing shape or notch shape is greatly affected by processing conditions corresponding to a depth direction of an etching shape, the optimization of the processing condition for each depth is necessary. However, in the related art, since a cross-sectional shape cannot be estimated, the optimization of the processing condition for each depth cannot be handled.

Therefore, an object of the invention is to provide a system that detects a shape defect that cannot be obtained only by top-view geometric dimension data and derives an optimal processing condition in a depth direction of an etching shape.

### Solution to Problem

In order to solve the above problems, there is provided one representative semiconductor device manufacturing system according to the invention that performs control of an etching parameter to obtain a desired processing result of a semiconductor manufacturing apparatus, in which optimization of an etching parameter is executed in at least one of etching steps based on correlation data between the etching parameter and a change amount of a feature and based on a change amount of an acquired feature, the feature is a value obtained from secondary electron data or interference light data from a surface of a sample, the change amount of the feature is a difference between the feature and a target value of the feature, the change amount of the acquired feature is a change amount of the feature acquired for each depth of an etching shape formed by the semiconductor manufacturing apparatus, and each of the etching steps is a step of processing conditions of the semiconductor manufacturing apparatus corresponding to each depth of the etching shape formed by the semiconductor manufacturing apparatus.

### Advantageous Effects of Invention

According to the invention, it is possible to detect a shape defect that cannot be obtained only by top-view geometric dimension data and derive an optimum processing condition in a depth direction of an etching shape. A user can optimize an etching processing recipe (processing condition), which is nondestructive and does not cause a device defect, without observing a cross section of a wafer when or before a device defect occurs. Further, by subdividing the etching step in an etching depth direction and running the optimization cycle, the user can reduce a trial count of the etching parameter optimization required until an ideal device electrical property is obtained.

Problems, configurations, and effects other than those described above will become apparent by description of the following embodiments.

### BRIEF DESCRIPTION OF DRAWINGS

FIG. 1 is a schematic diagram illustrating a semiconductor device manufacturing system according to a first embodiment.

FIG. 2 is a correlation diagram between a pattern shape and a secondary electron profile.

FIG. 3 is a correlation diagram between a pattern shape and a secondary electron profile under a predetermined etching parameter.

FIG. 4A is a flowchart illustrating an example of an etching parameter optimization cycle.

FIG. 4B is a flowchart illustrating another example of the etching parameter optimization cycle.

FIG. 5 is a correlation diagram between an etching step and an optimization cycle.

FIG. 6 is a correlation diagram between a trial count and a device defect ratio.

FIG. 7 is a conceptual diagram of a prediction model of an optimal etching parameter according to a second

### DESCRIPTION OF EMBODIMENTS

Hereinafter, embodiments of the invention will be described with reference to the drawings. The invention is not limited to the embodiments. In the description of the drawings, the same portions are denoted by the same reference signs.

In one example of an embodiment of the invention, there is provided a server that stores, as correlation data, a change amount of a feature obtained from a secondary electron profile obtained from a top view of a wafer (also referred to as a sample) by a CD-SEM and an etching parameter in an etching step corresponding to a depth direction of an etching shape, and performs etching parameter control in a semiconductor manufacturing apparatus based on the correlation data. Hereinafter, embodiments will be described with reference to the drawings.

### First Embodiment

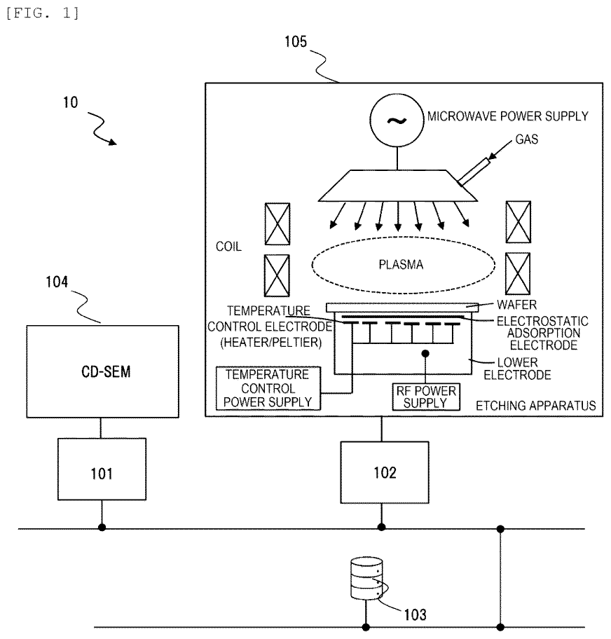

A first embodiment of the invention will be described with reference to FIG. 1. FIG. 1 is a schematic diagram illustrating a semiconductor device manufacturing system according to the first embodiment. A semiconductor device manufacturing system 10 includes an apparatus group including semiconductor manufacturing apparatus (an etching apparatus) 105, a CD-SEM PC 101, a semiconductor manufacturing apparatus PC 102, and a semiconductor inspection apparatus 104 (for example, a CD-SEM), and a server 103. An object of the drawing is to illustrate performance improvement of an important semiconductor device manufacturing system in semiconductor manufacturing.

A processing recipe for performing etching processing is input to the semiconductor manufacturing apparatus PC 102 or transferred from the server 103 to the PC 102, and the processing recipe is executed. After the execution, the etching apparatus 105 transmits an instruction value corresponding to contents of the processing recipe to each device in the etching apparatus to perform etching processing. Devices and components illustrated in FIG. 1 are main devices and components, and include a wafer temperature control power supply, a temperature control electrode (heater/Peltier), an RF power supply for applying a radio frequency, a microwave power generator for generating plasma, a gas for generating plasma, a magnetic field generation coil for adjusting a plasma density, an electrostatic adsorption electrode (an electrostatic chuck), and a lower electrode. A wafer that is a sample is placed on a sample stage and is etched by plasma processing. The executed processing recipe can be stored in the server 103 via the semiconductor manufacturing apparatus PC 102.

In the embodiment, as the etching parameter control, two systems related to a temperature of a sample and a plasma characteristic such as a plasma density, which have a large influence on a defective shape of a device, will be described separately. That is, the systems are a sample temperature control system and a plasma characteristics control system. Here, an etching parameter can directly control a device, and is different from a plasma characteristic, a temperature of a sample and the like that are results (collectively referred to as an etching environment) after adjusting an etching parameter.

An etching parameter of the temperature related to the sample temperature control system is an instruction value to a system (temperature control system) for controlling a temperature of a temperature control element inside the sample stage, such as a heater element or a Peltier element, and is, for example, an instruction value for controlling a current value of a power supply connected to the heater element. The etching parameter of the temperature includes a current value and on/off frequencies of a switch for bypassing and releasing a current.

An etching parameter of the plasma characteristics related to the plasma characteristics control system are roughly divided into the following three. The three are an instruction value to a system for controlling power for plasma generation (for example, a radio frequency power supply that supplies radio frequency power for plasma generation), an instruction value to a distribution control system of plasma after plasma generation, and an instruction value to a bias application system for drawing ions or electrons converted into plasma from plasma after plasma generation to a sample stage (for example, a radio frequency power supply that supplies radio frequency power to the sample stage). The instruction value to the system for controlling power for plasma generation includes, for example, a voltage value, a frequency value, and an application time of microwave power. The instruction value to the distribution control system of plasma after plasma generation includes, for example, a current value of a coil power supply and a phase control plate angle on a microwave path. The instruction value to the bias application system for drawing ions or electrons converted into plasma to a sample stage includes, for example, a voltage value, a frequency value, an application time, a variable capacitor capacitance value for matching, and a variable reactance value of an RF power supply connected to the sample stage.

An etched sample is conveyed to the semiconductor inspection apparatus 104 (for example, a CD-SEM). In FIG. 1, a CD-SEM recipe is input to the CD-SEM PC 101 and predetermined measurement is performed. Here, an electron beam is used in the measurement, and a feature is calculated based on a secondary electron amount (secondary electron data) after irradiation with a primary electron beam. Here, a feature obtained from an intensity profile of the secondary electron amount (a secondary electron profile) is used as a representative feature. There are various other features such as a feature using illuminance data and a feature obtained by differentiating the intensity profile (a feature obtained from the secondary electron profile derived from an etching shape of the sample may be referred to as a profile feature). A measurement result can be stored in the server 103 via the PC 101.

By using the stored measurement data, a sample yield is visualized based on a feature distribution in a sample surface, and when a calculated yield value cannot be satisfied, a processing recipe for performing the etching processing again is corrected. Even when CD values are the same, if features are different, it is considered that there is a defect in a pattern shape. A more detailed description will be made below.

### Secondary Electron Profile

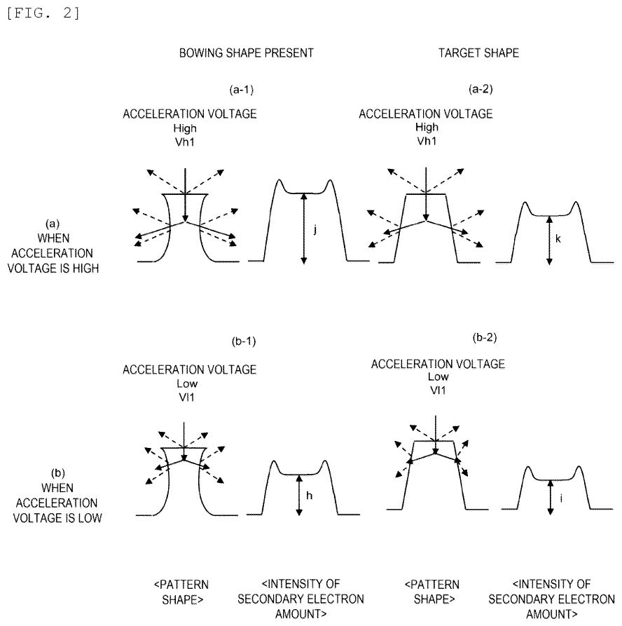

FIG. 2 is a correlation diagram between a pattern shape and a secondary electron profile. In FIG. 2, a schematic diagram of a pattern shape of a device is shown on the left, and a schematic diagram of an intensity profile of a secondary electron amount (a secondary electron profile) is shown on the right. All Top CD values of pattern shapes in FIG. 2 are the same. Since a difference in the secondary electron amount occurs depending on a magnitude of an acceleration voltage, there is an optimum acceleration voltage at which it is easy to extract a defective shape. Here, a bowing shape is described as an example of the defective shape, and a concept how a secondary electron profile changes when the acceleration voltage is high and when the acceleration voltage is low and which one is optimum will be illustrated. A pattern shape of a device may be referred to as an etching shape when the device is to be formed by etching.
(a) of FIG. 2 illustrates a case where an acceleration voltage as an application voltage to primary electrons is high (acceleration voltage: Vh1). (a-1) illustrates a pattern shape having a bowing shape (defective shape), and since a penetration depth of the primary electrons of the acceleration voltage is deep, the amount of secondary electrons permeating from side walls of the pattern is large, and accordingly, the secondary electron amount intensity also increases. Therefore, since j-k is large, which is a difference (a change amount) between a feature (the secondary electron amount intensity at the center of a pattern Top surface) of the pattern shape having the bowing shape whose lateral width of the pattern shape is smaller and a feature of a target shape whose lateral width of the pattern shape indicated in (a-2) is a normal value, the detection of

On the other hand, (b) of FIG. 2 illustrates a case where an acceleration voltage as an application voltage applied to primary electrons is low (acceleration voltage: Vl1). Since h−i is small, which is a difference in secondary electron amount intensity (a change amount of feature) between a case of the bowing shape indicated in (b-1) and a case of a target shape indicated in (b-2), the detection of the bowing shape is difficult.

As described above, since the ease of detection of a pattern shape defect is changed by adjusting the acceleration voltage applied to the primary electrons at the time of irradiating with an electron beam, it is important to adjust the acceleration voltage to be optimum.

As described above, since the profile feature also includes information on an etching depth direction of an etching shape, by calculating a difference of features in a sample surface, it is possible to calculate a defect such as a bowing shape in the etching depth direction that cannot be obtained only by planar dimension data obtained from a top view. A more detailed change in feature may be calculated by calculating a change in the feature by tilting a sample using a tilt function by the CD-SEM. Alternatively, the change in the feature may be calculated by tilting the electron beam irradiated to the sample. As a method of performing irradiation with the electron beam, the electron beam itself may be tilted or the sample stage on which the sample is placed may be tilted.

### Feature and Etching Parameter

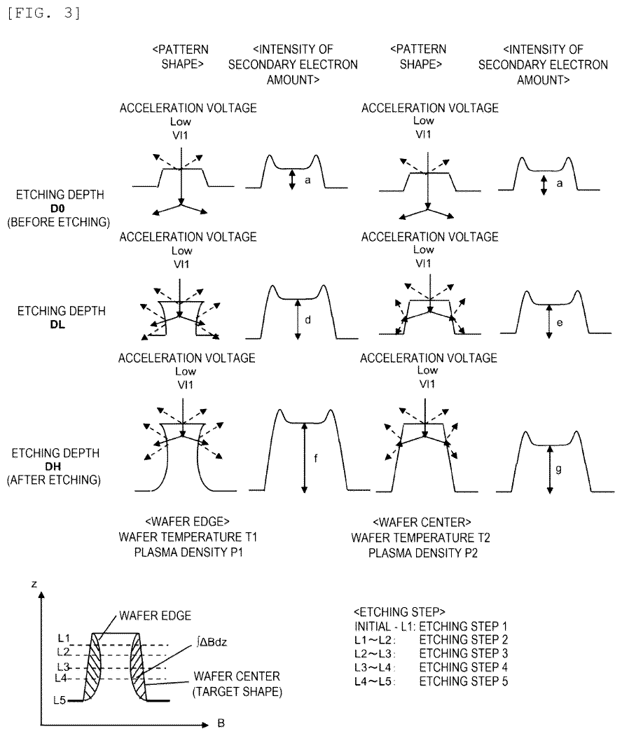

Next, a correlation between a feature and an etching parameter will be described. FIG. 3 is a correlation diagram between a pattern shape and a secondary electron profile under a predetermined etching parameter. As an example, a pattern shape and a feature at an outer peripheral portion (a sample edge or a wafer edge) of a sample, a pattern shape and a feature at a central portion (a sample center or a wafer center) of the sample, and temperature environments and plasma density environments at respective locations are shown. Here, for example, a device at the sample center has a pattern target shape, a temperature at the sample center is T2, and a plasma density at the sample center is P2. A temperature at the sample edge is T1 and a plasma density at the sample edge is P1 at a place where a device at the sample edge has a bowing shape and a defect occurs. FIG. 3 shows a graph schematically illustrating pattern shapes at a sample edge and a sample center with a vertical axis of z and a horizontal axis of B. L1 to L4 are film type switching lines. A shaded portion indicates a shape difference between the sample edge and the sample center. An area (an area difference) of a shape difference portion is ∫ΔBdz. Here, there are two methods, that is, a method of calculating the ∫ΔBdz to optimize the etching parameter and a method of optimizing the etching parameter without calculating the ∫ΔBdz, and the two methods are described as below.

### Method 1

Method 1 is a method of performing etching parameter control without specifying ∫ΔBdz.

First, ∫ΔBdz can be expressed as Formula 1 using a function Q.

∫ΔBdz=Q((f−a)−(g−a)) Formula 1

Next, when a sample temperature difference ΔT=T1−T2 and a plasma density difference ΔP=P1−P2, ∫ΔBdz can be expressed as Formula 2 using a function R.

∫ΔBdz=R(ΔT, ΔP) Formula 2

From Formulas 1 and 2,
Q(f−g)=R(ΔT, ΔP),
and thus, f−g can be expressed as Formula 3 using a function Z.

f−g=Z(ΔT, ΔP) Formula 3

Here, ideally, since f−g=0,
values of T and P at which Z(ΔT, ΔP)=0 may be calculated according to Formula 3.

### Method 2

Method 2 is a method of performing etching parameter control by specifying ∫ΔBdz.

First, ∫ΔBdz is calculated by CD measurement at real time at L1 to L4 based on an optical critical dimension (OCD). At this time, measurement points in a depth direction may be stacked films having different film types. In the case of the same films, measurement may be performed by dividing a sample using an SEM or TEM. As a matter of course, the SEM and TEM can also be used for stacked films.

∫ΔBdz can be expressed as Formula 4 using a predetermined function R.

∫ΔBdz=R(ΔT, ΔP) Formula 4

Here, ideally, since ∫ΔBdz=0, values of T and P at which R(ΔT, ΔP)=0 may be calculated according to Formula 4.

There is no particular limitation on derivation with a function described in the present disclosure, and inductive calculation from experiments can be performed.

Since Method 1 is employed in the first embodiment, it is not necessary to calculate a geometric dimensional difference. Method 2 can be employed in a second embodiment to be described later. A process introducing an optimization cycle as a method of optimizing an etching parameter according to Method 1 will be described below with reference to a flowchart. In addition to the following description, a temperature of a sample in the sample temperature control system, plasma characteristics in the plasma characteristics control system, and the like can be appropriately selected or combined as etching parameters.

### Optimization Cycle (1)

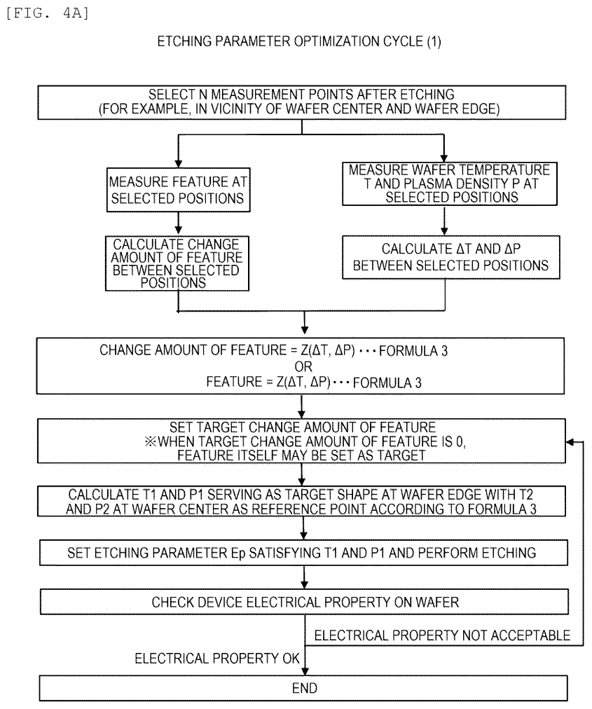

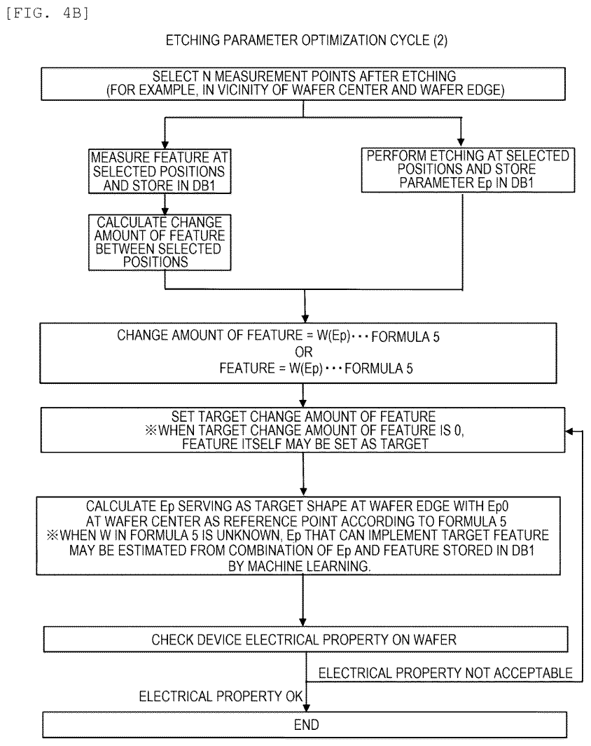

FIG. 4A is a flowchart illustrating an example of an etching parameter optimization cycle.

First, after sample etching, N measurement points are selected. N is a number larger than 1 for the number of parameters to be calculated. For example, in the embodiment, there are two points, that is, a sample center and a sample edge. In the embodiment, in order to simplify description, it is assumed that a plasma density is not changed and a parameter to be calculated is only a temperature, and thus the above two measurement points are sufficient.

Next, a sample temperature T and a plasma density P at a selected position are measured, and a feature is also measured.

Next, a sample temperature difference ΔT and a plasma density difference ΔP between the sample center and the sample edge are calculated, and a change amount (for example, f−g in FIG. 3) that is a difference between features is calculated.

Next, referring to Formula 3 that is correlation data between the etching parameter and the change amount of the feature, a target f−g and T2 and P2 at the sample center, which is a reference point, are set in order to calculate a value of the function Z. As described above, when P1 at the sample edge is the same as P2, T1 at the sample edge is calculated according to Formula 3. When the target difference f−g between the features is 0, the feature itself may be set as a target, and in this case, T1 is calculated according to Formula 3. This is a temperature at the sample edge for forming a target shape.

Here, a temperature in the vicinity of an edge of a sample stage is adjusted as an etching parameter Ep that satisfies the T1. In consideration of a heat input balance from plasma, the temperature in the vicinity of the edge of the sample stage is adjusted such that a temperature of the sample edge is T1, and then etching is performed. For example, the temperature in the vicinity of the edge of the sample stage is adjusted by controlling a current value of the heater element or the Peltier element inside the sample stage that is provided in the vicinity of the sample edge or controlling a temperature of a refrigerant provided in the vicinity of the edge of the sample.

Next, an electrical property of the device on the sample is checked. When requirements are satisfied, the process is ended, and when the requirements are not satisfied, the optimization of the etching parameter is implemented by repeating from setting the target difference of the feature (the etching parameter optimization cycle (1)).

### Optimization Cycle (2)

In the description of FIG. 4A, it is assumed that the sample temperature and the plasma density are measured to calculate a correlation with the feature, and an etching parameter capable of reproducing the optimum sample temperature and plasma density is calculated. On the other hand, there is also a method in which a correlation between a difference in feature and an etching parameter is calculated directly without measuring the sample temperature or the plasma density, and the etching parameter is calculated directly. FIG. 4B is a flowchart illustrating another example of the etching parameter optimization cycle.

First, after sample etching, N measurement points are selected. N is a number larger than 1 for the number of parameters to be calculated. For example, in the embodiment, there are two points, that is, a sample center and a sample edge.

Next, the etching parameter Ep at the selected position is stored in a database (DB1) in the server. A feature at the selected position is measured and stored in the DB1.

Next, a change amount (for example, f−g in FIG. 3) that is a difference between features at the sample center and the sample edge, which are the selected positions, is calculated.

Data about a distribution of the etching parameter Ep and the feature in a sample plane is accumulated in the DB1, and the etching parameter Ep having a high correlation from a predetermined feature can be calculated from the DB1 and controlled so that the in-plane distribution is uniform. Here, a difference (for example, f−g) between the features and the etching parameter Ep can be expressed as Formula 5 using the

f−g=W(Ep) Formula 5

Next, referring to Formula 5 that is correlation data between the etching parameter and the change amount of the feature, a target f−g is set in order to calculate a value of the function W. The etching parameter Ep, which is a target shape of the sample edge, is calculated from a sample center Ep0 that is a reference point according to Formula 5, and the etching is performed. When the target difference f−g between the features is 0, the feature itself may be set as a target, and in this case, Ep is calculated according to Formula 5. When W in Formula 5 is unknown, Ep that can implement the target feature may be estimated from a combination of Ep and feature stored in DB1 based on: machine learning (see the second embodiment).

Next, an electrical property of the device on the sample is checked. When requirements are satisfied, the process is ended, and when the requirements are not satisfied, the optimization of the etching parameter is implemented by repeating from setting the target difference of the feature (the etching parameter optimization cycle (2)).

In the above-described flow, the etching parameter Ep can be calculated without going through a difficult step of measuring the sample temperature and the plasma density, but since the number of parameters for obtaining the correlation between the difference in feature and Ep, the parameter estimation is difficult.

### Etching Step and Optimization Cycle

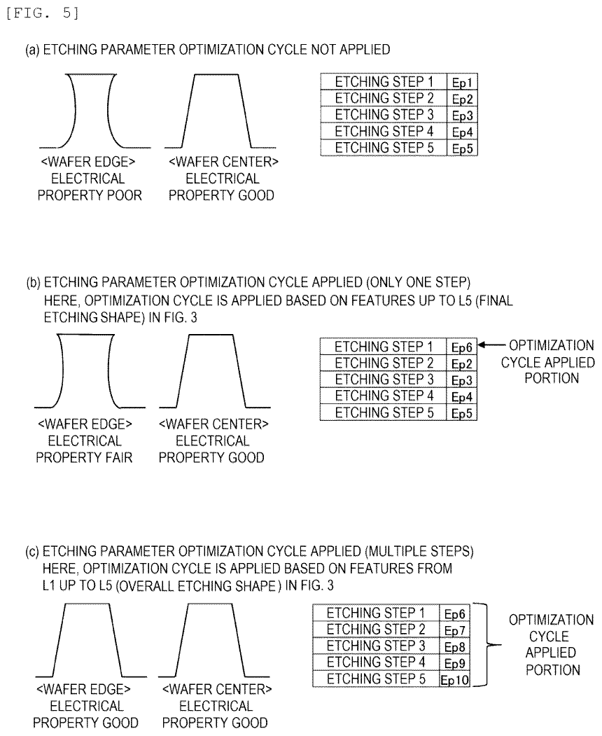

The above-described etching parameter optimization cycle can be individually applied to each step (hereinafter referred to as an “etching step”) in which a processing recipe of the semiconductor manufacturing apparatus corresponding to each predetermined etching depth is executed (see FIG. 3). FIG. 5 is a correlation diagram between an etching step and an optimization cycle. In FIG. 5, a case of five etching steps is taken as an example. The optimization cycle to be applied may be any of those in FIGS. 4A and 4B.
(a) of FIG. 5 illustrates a case where no etching parameter optimization cycle is applied. In this case, as a matter of course, a defective shape such as a bowing shape cannot be controlled and appears remarkably.
(b) of FIG. 5 illustrates a case where the optimization cycle is applied only to an etching step 1. If a contribution ratio of the etching step 1 to a pattern shape is large, a significant improvement is observed as compared with that in (a) of FIG. 5, and it is necessary to examine the contribution ratio separately.
(c) of FIG. 5 illustrates a case where the optimization cycle is applied to all the etching steps. In this case, it is not necessary to examine the contribution ratio, and a significant improvement can be achieved as compared with that in (a) of FIG. 5.

If an etching step having a high contribution ratio to the etching shape is known in advance, a method of applying the optimization cycle to only a specific etching step as illustrated in (b) of FIG. 5 is preferable in terms of time efficiency of optimization. On the other hand, when the contribution ratio is unknown, it may be preferable in terms of time efficiency of optimization that the optimization cycle is applied to all the etching steps as illustrated in (c) of FIG. 5. In summary, when it does not take long to specify the contribution ratio to the etching shape for each etching step, the method in (b) of FIG. 5 is favorable, and when it takes time to specify the contribution ratio, the method in (c) of FIG. 5 is favorable.

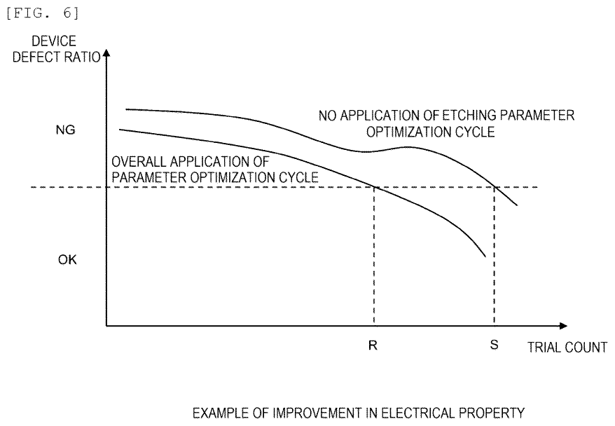

Next, trial counts required until an electrical property of the device satisfies the requirements are compared between a case where the etching parameter optimization cycle is applied and a case where the etching parameter optimization cycle is not applied. Here, the trial refers to acts of performing etching processing by changing the etching parameter so as to approach an expected electrical property and measuring the electrical property. FIG. 6 is a correlation diagram between a trial count and a device defect ratio. A vertical axis represents the device defect ratio according to check of the electrical property, and a horizontal axis represents the trial count of etching a sample. A relationship between the trial count and the optimization cycle application for reaching a threshold, at which it is determined that the electrical property satisfies the requirements and are OK, is represented by Formula 6.

R (overall application of optimization cycle)<S (no application of optimization cycle) Formula 6

From Formula 6, it is understood that the trial count is reduced by applying the optimization cycle, and the total cost including labor costs and apparatus operation costs can be reduced.

In the first embodiment, an example is illustrated in which the etching parameter is optimized for each etching step corresponding to a depth direction of the etching shape by using a spatial difference in feature. Here, although the description is given based on a feature calculated from a secondary electron profile in the CD-SEM, the same flow of etching parameter optimization can be applied to a feature calculated from an interference light profile in an OCD.

### Second Embodiment

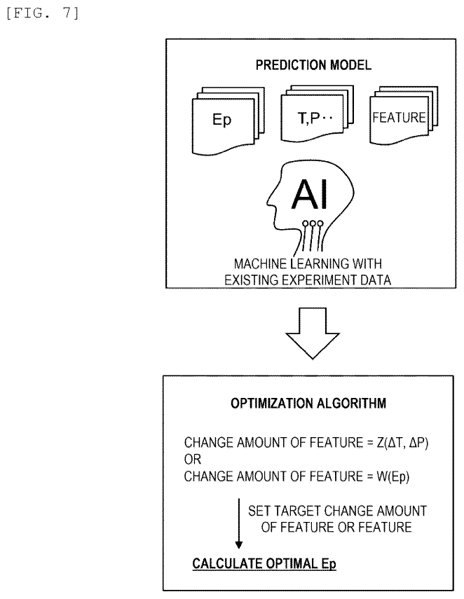

In the first embodiment, the most time-consuming part is the part of optimizing an etching parameter from a change amount of a feature. In the second embodiment, an example in which machine learning is used for processing of the optimization part will be described. FIG. 7 is a conceptual diagram of a prediction model of an optimal etching parameter in the second embodiment.

In a database (DB1), data such as a measured feature, a difference in feature, an etching parameter Ep, a plasma characteristic, and a sample temperature is stored in association with each other. By using the stored data as existing experiment data, functions Z and W in the diagram can be obtained using a machine learning method. When a change amount of a feature is input to Z or W, an optimal etching parameter Ep can be calculated. Alternatively, it is also possible to estimate Ep that reproduces a change amount of a feature f achieving a target shape by using AI without directly calculating Z or W.

Although embodiments of the invention have been described above, the invention is not limited to the embodiments described above, and various changes can be made without departing from the gist of the invention.

For example, although the server described as a component that performs the etching parameter control in the embodiments described above, a virtual area, a PC terminal, or a mobile terminal may be used instead of the server, and the same effects can be obtained not only by a communication method of SMB communication, but also by FTP communication, NFS communication, and the like.

Further, although an example in which the etching parameter optimization is executed by the server has been described in the embodiments described above, the etching parameter optimization may be executed by an application installed on a platform provided in the semiconductor device manufacturing system.

Although an etching apparatus is described as an example of a semiconductor manufacturing apparatus in the embodiments described above, the same effects can be obtained by other manufacturing apparatuses such as a plasma CVD apparatus, an ashing apparatus, a surface modification apparatus, and the like. Although a CD-SEM is described as an example of a semiconductor inspection apparatus in the embodiments described above, the same effects can be obtained by other inspection apparatuses such as OCD, TEM, and XRR.

Aspects that may be contents of the invention will be described below, and the invention is not limited thereto.

### Aspect 1

A semiconductor device manufacturing system that performs control of an etching parameter to obtain a desired processing result of a semiconductor manufacturing apparatus, in which
optimization of an etching parameter is executed in at least one of etching steps based on correlation data between the etching parameter and a change amount of a feature and based on a change amount of an acquired feature,
the feature is a value obtained from secondary electron data or interference light data from a surface of a sample,
the change amount of the feature is a difference between the feature and a target value of the feature,
the change amount of the acquired feature is a change amount of the feature acquired for each depth of an etching shape formed by the semiconductor manufacturing apparatus, and
each of the etching steps is a step of processing conditions of the semiconductor manufacturing apparatus corresponding to each depth of the etching shape formed by the semiconductor manufacturing apparatus.

### Aspect 2

A semiconductor device manufacturing system that performs control of an etching parameter to obtain a desired processing result of a semiconductor manufacturing apparatus, in which
optimization of an etching parameter is executed in at least one of etching steps based on correlation data between a temperature of a sample or a plasma characteristic and a change amount of a feature and based on a change amount of an acquired feature,
the feature is a value obtained from secondary electron data or interference light data from a surface of the sample,
the change amount of the feature is a difference between the feature and a target value of the feature,
the change amount of the acquired feature is a change amount of the feature acquired for each depth of an etching shape formed by the semiconductor manufacturing apparatus, and
each of the etching steps is a step of processing conditions of the semiconductor manufacturing apparatus corresponding to each depth of the etching shape formed by the semiconductor manufacturing apparatus.

### Aspect 3

The semiconductor device manufacturing system according to aspect 1 or 2, in which
the optimization of the etching parameter is to optimize an instruction value to a temperature control system of a sample stage on which the sample is placed.

### Aspect 4

The semiconductor device manufacturing system according to any one of aspects 1 to 3, in which
the optimization of the etching parameter is to optimize an instruction value to a radio frequency power supply that supplies radio frequency power for generating plasma, and optimize an instruction value to a radio frequency power supply that supplies radio frequency power to a sample stage on which the sample is placed.

### Aspect 5

The semiconductor device manufacturing system according to any one of aspects 1 to 4, in which
the feature is obtained while changing a voltage applied to primary electrons of a CD-SEM.

### Aspect 6

The semiconductor device manufacturing system according to any one of aspects 1 to 5, in which
an etching parameter corresponding to the change amount of the feature is estimated using machine learning.

### Aspect 7

The semiconductor device manufacturing system according to any one of aspects 1 to 6, in which
the change amount of the feature is a difference between a feature at an edge of the sample and a feature at a center of the sample.

### Aspect 8

The semiconductor device manufacturing system according to any one of aspects 1 to 7, further including:
a platform on which an application for optimizing the etching parameter is installed.

### Aspect 9

A semiconductor device manufacturing method for performing control of an etching parameter to obtain a desired processing result of a semiconductor manufacturing apparatus, the method including steps of:
acquiring a feature from secondary electron data from a surface of a sample or interference light data; and
optimizing an etching parameter in at least one of etching steps based on correlation data between the etching parameter and a change amount of a feature and based on a change amount of an acquired feature, in which
the change amount of the feature is a difference between the acquired feature and a target value of the feature,
the change amount of the acquired feature is a change amount of the feature acquired for each depth of an etching shape formed by the semiconductor manufacturing apparatus, and
each of the etching steps is a step of processing conditions of the semiconductor manufacturing apparatus corresponding to each depth of the etching shape formed by the semiconductor manufacturing apparatus.

### Aspect 10

A semiconductor device manufacturing method for performing control of an etching parameter to obtain a desired processing result of a semiconductor manufacturing apparatus, the method including steps of:
acquiring a feature from secondary electron data from a surface of a sample or interference light data; and
optimizing an etching parameter in at least one of etching steps based on correlation data between a temperature of the sample or a plasma characteristic and a change amount of a feature and based on a change amount of an acquired feature, in which
the change amount of the feature is a difference between the acquired feature and a target value of the feature,
the change amount of the acquired feature is a change amount of the feature acquired for each depth of an etching shape formed by the semiconductor manufacturing apparatus, and
each of the etching steps is a step of processing conditions of the semiconductor manufacturing apparatus corresponding to each depth of the etching shape formed by the semiconductor manufacturing apparatus.

### Aspect 11

A server that is provided for the semiconductor device manufacturing system according to any one of aspects 1 to 8 and in which the optimization of the etching parameter is executed.

### REFERENCE SIGNS LIST

10: semiconductor device manufacturing system
101: CD-SEM PC
102: semiconductor manufacturing apparatus PC
103: server
104: semiconductor inspection apparatus
105: semiconductor manufacturing apparatus

1. A semiconductor device manufacturing system that performs control of an etching parameter to obtain a desired processing result of a semiconductor manufacturing apparatus, comprising:
a processor,
wherein
the processor is configured to perform optimization of an etching parameter is executed in at least one of etching steps based on correlation data between the etching parameter, a temperature of a sample, or a plasma characteristic and a change amount of a feature and based on a change amount of an acquired feature,
the feature is a value obtained from secondary electron data or interference light data from a surface of a sample,
the change amount of the feature is a difference between the feature and a target value of the feature,
the change amount of the acquired feature is a change amount of the feature acquired for each depth of an etching shape formed by the semiconductor manufacturing apparatus, and
each of the etching step is a step of processing conditions of the semiconductor manufacturing apparatus corresponding to each depth of the etching shape formed by the semiconductor manufacturing apparatus.

2. (canceled)

3. The semiconductor device manufacturing system according to claim 1, wherein
the optimization of the etching parameter is to optimize an instruction value to a temperature control system of a sample stage on which the sample is placed.

4. The semiconductor device manufacturing system according to claim 1, wherein
the optimization of the etching parameter is to optimize an instruction value to a radio frequency power supply that supplies radio frequency power for generating plasma, and optimize an instruction value to a radio frequency power supply that supplies radio frequency power to a sample stage on which the sample is placed.

5. The semiconductor device manufacturing system according to claim 1, wherein
the feature is obtained while changing a voltage applied to primary electrons of a CD-SEM.

6. The semiconductor device manufacturing system according to claim 1, wherein
an etching parameter corresponding to the change amount of the feature is estimated using machine learning.

7. The semiconductor device manufacturing system according to claim 1, wherein
the change amount of the feature is a difference between a feature at an edge of the sample and a feature at a center of the sample.

8. The semiconductor device manufacturing system according to claim 1, further comprising:
a platform on which an application for optimizing the etching parameter is installed.

9. A semiconductor device manufacturing method for performing control of an etching parameter to obtain a desired processing result of a semiconductor manufacturing apparatus, the method comprising steps of:
acquiring a feature from secondary electron data or interference light data from a surface of a sample; and
optimizing an etching parameter in at least one of etching steps based on correlation data between the etching parameter, a temperature of a sample, or a plasma characteristic and a change amount of a feature and based on a change amount of an acquired feature, wherein
the change amount of the feature is a difference between the acquired feature and a target value of the feature,
the change amount of the acquired feature is a change amount of the feature acquired for each depth of an etching shape formed by the semiconductor manufacturing apparatus, and
each of the etching step is a step of processing conditions of the semiconductor manufacturing apparatus corresponding to each depth of the etching shape formed by the semiconductor manufacturing apparatus.

10. (canceled)

11. A server that is provided for the semiconductor device manufacturing system and in which the optimization of the etching parameter is executed, comprising:
the server; and
a communications interface between the service and the semiconductor device manufacturing system, wherein
the server is configured to perform optimization of an etching parameter is executed in at least one of etching steps based on correlation data between the etching parameter, a temperature of a sample, or a plasma characteristic and a change amount of a feature and based on a change amount of an acquired feature,
the feature is a value obtained from secondary electron data or interference light data from a surface of a sample,
the change amount of the feature is a difference between the feature and a target value of the feature,
the change amount of the acquired feature is a change amount of the feature acquired for each depth of an etching shape formed by the semiconductor manufacturing apparatus, and
each of the etching step is a step of processing conditions of the semiconductor manufacturing apparatus corresponding to each depth of the etching shape formed by the semiconductor manufacturing apparatus.
